(19) United States
(12) Patent Application Publication
(10) Pub. No.: US 2024/0104262 A1
(43) Pub. Date: Mar. 28, 2024

(54) METHOD FOR SCALING VEHICLE CRASH DUMMY MODEL

(71) Applicants: CHINA AUTOMOTIVE TECHNOLOGY AND RESEARCH CENTER CO., LTD, Tianjin (CN); CATARC AUTOMOTIVE TEST CENTER (TIANJIN) CO., LTD, Tianjin (CN)

(72) Inventors: Zhixin LIU, Tianjin (CN); Zhixin WU, Tianjin (CN); Weidong LIU, Tianjin (CN); Hong ZHENG, Tianjin (CN); Kai WANG, Tianjin (CN); Hong CHEN, Tianjin (CN); Bingxu DUAN, Tianjin (CN); Hanxiao ZHANG, Tianjin (CN)

(73) Assignees: CHINA AUTOMOTIVE TECHNOLOGY AND RESEARCH CENTER CO., LTD, Tianjin (CN); CATARC AUTOMOTIVE TEST CENTER (TIANJIN) CO., LTD, Tianjin (CN)

(21) Appl. No.: 18/190,119

(22) Filed: Mar. 27, 2023

(30) Foreign Application Priority Data
Sep. 19, 2022 (CN) 202211133843.X

(51) Int. Cl. G06F 30/20; G06T 19/20

(52) U.S. Cl. CPC G06F 30/20; G06T 19/20; G06T 2219/2016

(57) ABSTRACT

A method for scaling a vehicle crash dummy model, includes: obtaining a height ratio, a girth ratio, and a mass ratio of each part of a body shape of a target population to a reference population; calculating part scaling ratios of the target population to the reference population in a height direction and each direction in a girth plane according to the height ratio, the girth ratio, and the mass ratio; scaling simulation models of each part of a dummy simulation model of the reference population according to each scaling ratio; and assembling scaled models of each part, to obtain a dummy simulation model of the target population. This embodiment improves a shape simulation degree for a real human body of a dummy.

### CROSS-REFERENCE TO RELATED APPLICATIONS

This application claims priority to Chinese Patent Application No. 202211133843.X with a filing date of Sep. 19, 2022. The content of the aforementioned application, including any intervening amendments thereto, is incorporated herein by reference.

### TECHNICAL FIELD

Embodiments of the present disclosure relate to the field of vehicle crash dummy simulation modeling, in particular to a method for scaling a vehicle crash dummy model.

### DESCRIPTION OF RELATED ART

Vehicle passive safety is an important technical guarantee to protect life safety of drivers and passengers. For the vehicle passive safety, a vehicle crash test is required to be conducted to obtain injury data of a human body during a crash. A vehicle crash test dummy is a key test system for replacing a real human body to simulate injuries of the human body and evaluate the vehicle passive safety. Therefore, the vehicle crash test dummy is particularly important for accurately evaluating vehicle safety.

In an actual crash test, vehicle crash dummies are a series of products, including crash dummies having different body shapes. Crash dummies having various body shapes all play an important role in the test, and their measurement results can be used for directly determining the vehicle safety. For development of all types of vehicle crash dummies, a complex exploration process is required, a large volume of human body data need to be measured as a basis, and dummy structural performance is developed according to the measured data. As a result, a development process of a dummy simulation model is cumbersome, and support of mass data is required for all types of dummies. In order to simplify a crash dummy design program, human body scaling methods have been studied in the prior art, in which a three-dimensional model of a specific population is obtained through scaling on the basis of a dummy with a standard body shape. However, these scaling methods usually only consider size adjustment in a height direction, and thus obtaining uncoordinated human body models, and seldom simulating real body shapes.

### SUMMARY OF PRESENT INVENTION

Embodiments of the present disclosure provide a method for scaling a vehicle crash dummy model. By comprehensively considering heights, girths, and masses of each part of human body, the method solves a problem that an existing dummy simulation model after size adjustment is inconsistent with a real person in body shape.

In a first aspect, an embodiment of the present disclosure provides a method for scaling a vehicle crash dummy model, including:
obtaining a height ratio, a girth ratio, and a mass ratio of each part of a body shape of a target population to a reference population;
calculating part scaling ratios of the target population to the reference population in a height direction and each direction in a girth plane according to the height ratio, the girth ratio, and the mass ratio;
scaling simulation models of each part of a dummy simulation model of the reference population according to each scaling ratio; and
assembling scaled models of each part, to obtain a dummy simulation model of the target population.

In a second aspect, an embodiment of the present disclosure provides an electronic device, including:
one or more processors; and
a memory, used for storing one or more program, where
when the one or more programs are executed by the one or more processors, the one or more processors are enabled to implement the method for scaling a vehicle crash dummy model according to any of the embodiments.

In a third aspect, an embodiment of the present disclosure further provides a computer-readable storage medium storing a computer program, where the program, when executed by a processor, implements the method for scaling a vehicle crash dummy model according to any of the embodiments.

The embodiments of the present disclosure provide the method for scaling a vehicle crash dummy model, in which accurate height and girth dimensions of each part of a human body are selected, dimensional proportions in coordinate axis directions in scaling coordinate systems are corrected, and a scaling ratio of a simulation model of each part is calculated; and then each part of the dummy simulation model of the reference population is scaled according to the scaling ratio, and the obtained simulation model keeps basic proportions of a model contour in height and girth, satisfies the mass of each part of a real person and a dummy, is more in line with physical signs of a target population, and improves a shape simulation degree for a real human body of the dummy.

### BRIEF DESCRIPTION OF THE DRAWINGS

In order to describe technical solutions in specific embodiments of the present disclosure or in the prior art more clearly, the following briefly introduces the accompanying drawings required in the description of the specific embodiments or the prior art. Apparently, the accompanying drawings in the following description show only some embodiments of the present disclosure, and those of ordinary skill in the art can still derive other drawings from these drawings without any creative effort.

FIG. 1 is a flowchart of a method for scaling a vehicle crash dummy model according to an embodiment of the present disclosure.

FIG. 2 is a schematic diagram of a structure of a crash dummy according to an embodiment of the present disclosure.

FIG. 3 is a schematic diagram of a calf girth and height according to an embodiment of the present disclosure, where FIG. 3(a) is a schematic diagram of dividing a calf height of a target population into N equal parts, and FIG. 3(b) is a schematic diagram of dividing a calf height of a reference population into N equal parts.

FIG. 4 is a schematic diagram of a scaling coordinate system of each part according to an embodiment of the present disclosure.

FIG. 5 is a schematic diagram of a center-of-mass measuring instrument according to an embodiment of the present disclosure.

FIG. 6 is a schematic diagram of measuring a center of mass of a part according to an embodiment of the present disclosure.

FIG. 7 is a schematic diagram of an upper arm scaling coordinate system according to an embodiment of the present disclosure.

FIG. 8 is a schematic diagram of an assembled dummy simulation model of a target population according to an embodiment of the present disclosure.

FIG. 9 is a schematic diagram of a structure of an electronic device according to an embodiment of the present disclosure.

### DESCRIPTION OF THE EMBODIMENTS

In order to make objectives, technical solutions and advantages of the present disclosure clearer, the technical solutions of the present disclosure will be described clearly and completely below. Obviously, the described embodiments are only some rather than all embodiments of the present disclosure. Based on the embodiments of the present disclosure, all other embodiments obtained by those of ordinary skill in the art without any creative effort fall within the protection scope of the present disclosure.

In the description of the present disclosure, it should be noted that the orientation or position relationships indicated by the terms “center”, “upper”, “lower”, “left”, “right”, “vertical” “horizontal”, “inner”, “outer”, etc. are based on the orientation or position relationships shown in the accompanying drawings and are intended to facilitate the description of the present disclosure and simplify the description only, rather than indicating or implying that the device or element referred to must have a particular orientation or be constructed and operated in a particular orientation, and will not to be interpreted as limiting the present disclosure. Furthermore, the terms “first”, “second” and “third” are only for the sake of description, and cannot be understood as indicating or implying the relative importance.

In the description of the present disclosure, it should also be noted that, unless otherwise specified and defined, the terms “mounted”, “coupled” and “connected” should be generally understood, for example, the “connected” may be fixedly connected, detachably connected, integrally connected, mechanically connected, electrically connected, directly connected, or connected by a medium, or internal communication between two elements. For those of ordinary skill in the art, the specific meanings of the terms described above in the present disclosure may be construed according to specific circumstances.

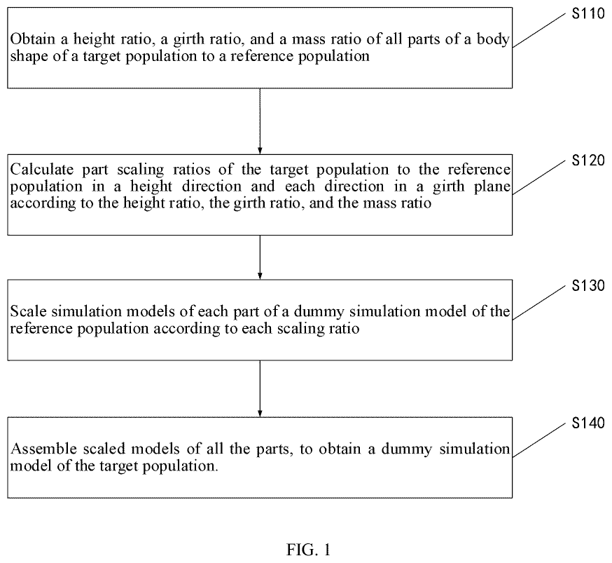

FIG. 1 is a flowchart of a method for scaling a vehicle crash dummy model according to an embodiment of the present disclosure. The method is suitable for scaling a dummy simulation model of a reference population to generate a dummy simulation model of a target population, and is executed by an electronic device. As shown in FIG. 1, the method specifically includes:

S110: a height ratio, a girth ratio, and a mass ratio of each part of a body shape of a target population to a reference population are obtained.

The target population refers to a population adapted to a physical dummy that needs simulation modeling, such as a Chinese population with 10 percentiles of adult male figures. The reference population refers to a population adapted to a physical dummy that has completed simulation modeling, such as a Chinese population with 50 percentiles of adult male figures. In this embodiment, a simulation model of a physical dummy conforming to physical signs of the reference population will be scaled to generate a dummy simulation model conforming to physical signs of a target population. The dummy simulation model may be used for manufacturing a physical dummy conforming to the physical signs of the target population, or for other subsequent simulation processing, which is not specifically limited in this embodiment.

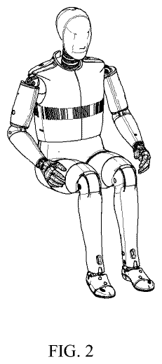

A crash dummy is composed of many parts, with a very complex structure. Optionally, as shown in FIG. 2, according to connection relationships of various parts of a physical dummy, human signs are discretized and divided into 16 human body parts, which include a head, a neck, a chest, buttocks, an upper left arm, a lower left arm, a left hand, an upper right arm, a lower right arm, a right hand, a left thigh, a left calf, a left foot, a right thigh, a right calf, and a right foot; and considering key parameters of human body, a height, a girth, and a mass are selected as important factors reflecting signs of each part, and the height ratio, the girth ratio and the mass ratio of each part of the target population to the reference population are obtained as input of subsequent operations.

Specifically, for any part, the mass ratio is obtained by the following formula:

$${R}_{m} = \frac{{T}_{S}}{{T}_{H}} \qquad ( 1 )$$

in the formula, m represents a different part, Rₘ represents a mass ratio of parts m of the target population and the reference population, T_{S} represents a mass of part m of the target population, and T_{H} represents a mass of part m of the reference population. Optionally, T_{S} and T_{H} may be means of multiple individuals. The following variables are similar, and details are not repeated here.

The height ratio at this part is obtained by the following formula:

$${λ}_{z} = \frac{{E}_{S}}{{E}_{H}} \qquad ( 2 )$$

in the formula, λ_{z} represents a height ratio of the part of the target population to the reference population, E_{S} represents a height of the part of the target population, and E_{H} represents a height of the part of the reference population.

However, obtaining of girths is special. Because the girths at different heights are different, this embodiment fuses girth ratios at different heights, to determine a final girth ratio. Optionally, a height of any part of the target population and a height of any part of the reference population are divided into N equal parts separately, where N is a natural number greater than 2; girth ratios of the target population and the reference population at N−1 division lines are determined separately; and the girth ratio of the part of the target population to the reference population is determined according to the girth ratios of the N−1 division lines.

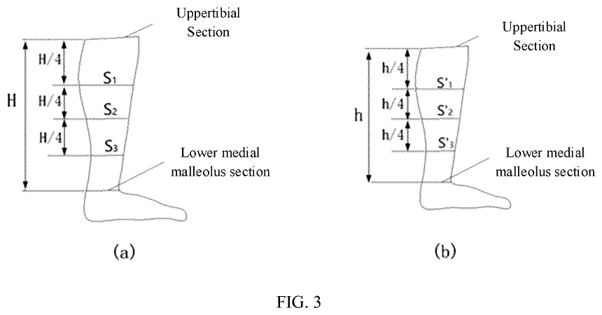

In a specific implementation, a calf part is used as an example, as shown in FIG. 3. A part between an upper tibial section and a lower medial malleolus section is the calf part. First, both a calf height H of the target population and a calf height h of the reference population are divided into four equal parts. FIG. 3(a) is a schematic diagram of dividing a calf height of a target population into four equal parts, and FIG. 3(b) is a schematic diagram of dividing a calf height of a reference population into four equal parts. Then, girth ratios of the target population to the reference population at three division lines are determined separately. Specifically, calf girths of the target population at the three division lines are S₁, S₂, and S₃, respectively, calf girths of the reference population at the three division lines are S′₁, S′₂, and S′₃, respectively, and the calf girth ratios of the target population to the reference population at the three division lines are

$$\frac{{S}_{1}}{{{S}^{′}}_{1}} , \frac{{S}_{2}}{{{S}^{′}}_{2}} , and \frac{{S}_{3}}{{{S}^{′}}_{3}} ,$$

respectively. Finally, a girth ratio of the part of the target population to the reference population is determined according to the girth ratios at the three division lines:

$$S = ( \frac{{S}_{1}}{{{S}^{′}}_{1}} + \frac{{S}_{2}}{{{S}^{′}}_{2}} + \frac{{S}_{3}}{{{S}^{′}}_{3}} ) / 3 \qquad ( 3 )$$

S120: part scaling ratios of the target population to the reference population in a height direction and each direction in a girth plane are calculated according to the height ratio, the girth ratio, and the mass ratio.

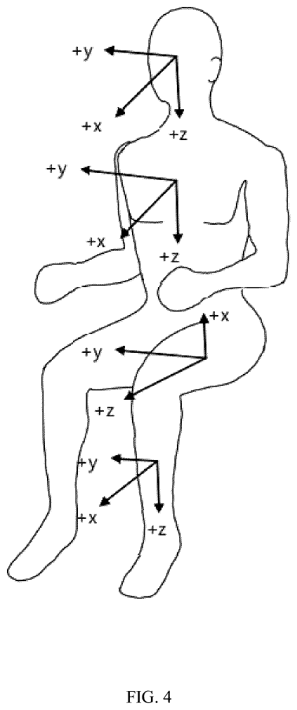

Optionally, for any part, each direction of the girth plane refers to two directions perpendicular to each other in the girth plane, and the two directions together with the height direction form a scaling coordinate system for model scaling in subsequent steps. As shown in FIG. 4, each part corresponds to its own scaling coordinate system, and the origin of the coordinate system may be set according to needs, for example, set at a center of mass of each part, which is not specifically limited in this embodiment. In this case, a process of determining a scaling ratio of any part along three coordinate axes of a scaling coordinate system includes the following steps.

Step 1: according to the girth ratio of the part, size ratios of the target population to the reference population in two directions perpendicular to each other in the girth plane are determined. In the scaling coordinate system, the two directions perpendicular to each other are denoted as direction x and direction y, respectively, and the size ratios of the target population to the reference population in the two directions are denoted as λₓ and λ_{y} respectively. According to a definition of girth, the following formula is obtained:

λₓ=λ_{y}=S (4)

Step 2: according to the mass ratio of the part, the height ratio and the size ratios are corrected to obtain the part scaling ratios of the target population to the reference population in the height direction and the two directions. Specifically, according to a definition of mass, the following formula is obtained:

Rₘ=λₓ×λ_{y}×λ_{z}×δₜₒₜₐₗ (5)

δₜₒₜₐₗ represents a correction coefficient for correcting a relationship between the product of the height ratio and the size ratio λₓ×λ_{y}×λ_{z} and the mass ratio, so that the both are more adapted to each other.

The correction coefficient may be decomposed into a correction coefficient δ_{z} in the height direction and correction coefficients δₓ and δ_{y} in the two directions in the girth plane, that is,

δₜₒₜₐₗ=δₓ×δ_{y}×δ_{z} (6)

Moreover, the three correction coefficients (δₓ, δ_{y}, and δ_{z}) are proportional to the corresponding size ratios (λₓ, λ_{y}, and λ_{z}). Therefore,

δₓ=δ_{y} (7)

(λₓ×λ_{y})/λ_{z}=(δδₓ×δ_{y})/δ_{z} (8)

Based on the above analysis, in solution of the part scaling ratio, the mass ratio Rₘ, the height ratio λ_{z}, and the size ratios λₓ and λ_{y} are substituted into formulas (5) to (8), to solve the correction coefficients δₓ, δ_{y}, and δ_{z} of the height ratio λ_{z} and the size ratios λₓ and λ_{y} are solved. Then, a part scaling ratio λ_{zcorrection} in the height direction, a part scaling ratio λ_{xcorrection} in one of the two directions, and a part scaling ratio λ_{ycorrection} in the other of the two directions of the target population to the reference population are calculated according to the following formulas:

λ_{zcorrection}=λ_{z}×δ_{z} (9)

λ_{xcorrection}=λₓ×δₓ (10)

λ_{ycorrection}=λ_{y}×δ_{y} (11)

The following table 1 shows size ratios (λₓ, λ_{y}, and λ_{z}) of some parts and corrected scaling ratios (λ_{xcorrection}, λ_{ycorrection}, and λ_{zcorrection}). It may be seen that the original size ratios are adjusted in the correction process, so that the correction results better adapt to the mass ratio and are more suitable for model scaling in subsequent steps.

TABLE 1
Values of Ratios

| | | | λₓ = | δₓ = | | | λ_{xcorrection} = |
|---|---|---|---|---|---|---|---|
| Part | Rₘ | λ_{z} | λ_{y} | δ_{y} | δ_{z} | λ_{zcorrection} | λ_{ycorrection} |
| Head | 0.903 | 0.989 | 0.984 | 0.977 | 0.985 | 0.969 | 0.961 |
| Neck | 0.826 | 0.996 | 0.962 | 0.959 | 0.964 | 0.96 | 0.923 |

S130: simulation models of each part of a dummy simulation model of the reference population are scaled according to each the scaling ratio.

For any part, in this step, the simulation model of the part of the reference population is scaled in the scaling coordinate system of the part, to obtain a simulation model of the part that is suitable for the target population. Specifically, this step includes the following steps.

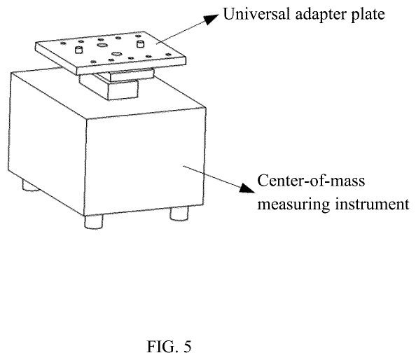

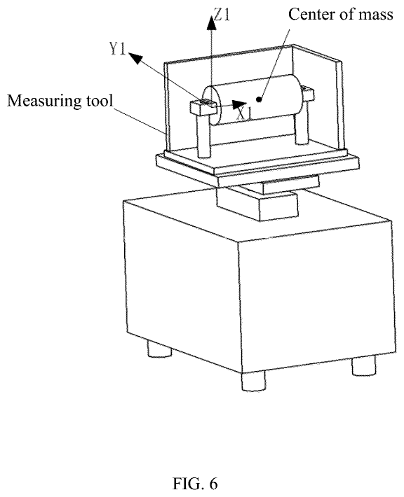

Step 1: a center of mass of any part of a physical dummy of the reference population under a specific posture is obtained. Optionally, the center of mass may be obtained by measuring the physical model of the part with a center-of-mass measuring instrument, and a test solution is as follows: first, a universal adapter plate is mounted on the center-of-mass measuring instrument, as shown in FIG. 5; a to-be-measured dummy part is mounted on a measuring tool, as shown in FIG. 6; the measuring tool is mounted on the universal adapter plate through an adapter plate connecting hole; then the center-of-mass measuring instrument are set to determine an origin of a measuring coordinate system and a corresponding spatial coordinate system (X1-Y1-Z1 coordinate system); and finally, the center-of-mass measuring instrument is run to measure center positions of mass of different parts of the dummy in the defined coordinate system.

Step 2: the simulation model of the part of the dummy simulation model of the reference population is adjusted to the specific posture. Specifically, the simulation model of the part is loaded in three-dimensional modeling software, and a coordinate origin and a coordinate system are defined, so that the coordinate system is consistent with the X1-Y1-Z1 coordinate system in the center-of-mass measuring instrument. Then, the simulation model of the part is placed according to a measurement position for positioning.

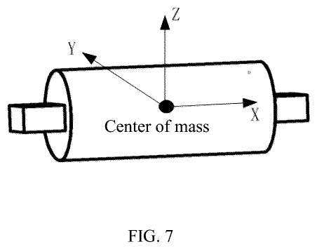

Step 3: the simulation model of the part is scaled according to each scaling coefficients based on the center of mass. First, coordinates of the center position of mass of the part are input into the coordinate system of the three-dimensional modeling software, where the coordinates are the origin of the scaling coordinate system of the part. Then, three directions of the scaling coordinate system are defined. Optionally, it is defined that the direction x is perpendicular to the front of the human body based on a standing posture, the direction y is perpendicular to a side of the human body, and the direction z is a standing height direction of the human body. FIG. 7 is a scaling coordinate system established at the upper arm.

S140: scaled models of each part are assembled to obtain a dummy simulation model of the target population.

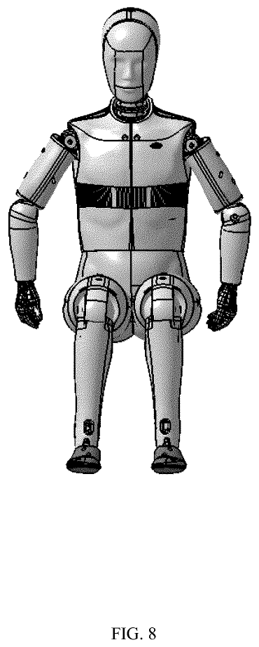

The scaled models of each part are assembled in the software, to obtain a scaled model of the dummy, as shown in FIG. 8. Optionally, the scaled models of each part are finely adjusted to meet assembly requirements of the software, and then assembled in the software. For example, some round holes used for assembly in the models become ovals due to scaling, and the ovals are readjusted to rounds to satisfy the assembly requirements.

This embodiment provides a method for scaling a vehicle crash dummy model, in which human body parts are reasonably divided, accurate height and girth dimensions are selected, dimensional proportions in coordinate axis directions in scaling coordinate systems are corrected, and a scaling ratio of a simulation model of each part is calculated; and then each part of a dummy simulation model of a reference population is scaled according to the scaling ratio, and the obtained simulation model keeps basic proportions of a model contour in height and girth, satisfies the mass of each part of a real person and a dummy, is more in line with physical signs of a target population, and improves simulation of real human body by a dummy. Based on the dummy model with a higher simulation degree, the production quality of the crash dummy may be further improved.

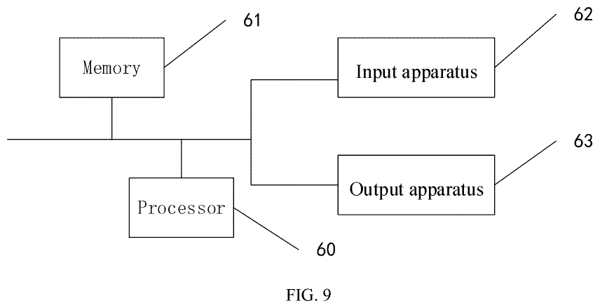

FIG. 9 is a schematic diagram of a structure of an electronic device according to an embodiment of the present disclosure. As shown in FIG. 9, the device includes a processor 60, a memory 61, an input apparatus 62, and an output apparatus 63. A quantity of the processor 60 in the device may be one or more. One processor 60 is taken as an example in FIG. 9. The processor 60, the memory 61, the input apparatus 62, and the output apparatus 63 in the device may be connected by a bus or in other ways, and they are connected by a bus in FIG. 9, for example.

As a computer-readable storage medium, the memory 61 may be used for storing a software program, a computer-executable program, and modules, such as program instructions/modules corresponding to the method for scaling a vehicle crash dummy model in the embodiments of the present disclosure. By running the software program, instructions, and modules stored in the memory 61, the processor 60 executes various functional applications of the device and data processing, that is, the foregoing method for scaling a vehicle crash dummy model is implemented.

The memory 61 may mainly include a program storage area and a data storage area, where the program storage area may store an operating system, and an application program required for at least one function; and the data storage area may store data created according to use of a terminal, etc. Moreover, the memory 61 may include a high speed random access memory, and may also include a non-volatile memory, such as at least one of a magnetic disk storage device, a flash memory, or other non-volatile solid-state storage devices. In some examples, the memory 61 may further include memories disposed remotely from the processor 60, and the remote memories may be connected to the device through a network. Examples of the network include, but are not limited to, the Internet, an intranet, a local area network, a mobile communications network, or a combination thereof.

The input apparatus 62 may be used for receiving input digit or character information, and generate key signal input related to user settings and function control of the device.

An embodiment of the present disclosure further provides a computer-readable storage medium storing a computer program, where the program, when executed by a processor, implements the method for scaling a vehicle crash dummy model according to any of the embodiments.

The computer storage medium in this embodiment of the present disclosure may employ any combination of one or more computer-readable media. The computer-readable medium may be a computer-readable signal medium or a computer-readable storage medium. For example, the computer-readable storage medium may be, but is not limited to, an electrical, magnetic, optical, electromagnetic, infrared, or semiconductor system, apparatus, or device, or any combination of the above. More specific examples (a non-exhaustive list) of the computer-readable storage medium include: an electrical connection having one or more wires, a portable computer disk, a hard disk, a random access memory (RAM), a read-only memory (ROM), an erasable programmable read-only memory (EPROM or flash memory), an optical fiber, a portable compact disk read-only memory (CD-ROM), an optical memory, a magnetic memory, or any suitable combination of the above. Herein, the computer-readable storage medium may be any tangible medium containing or storing a program that may be used by an instruction execution system, apparatus, or device, or a combination thereof.

The computer-readable signal medium may include a data signal that is propagated in a baseband or as part of a carrier wave, in which computer-readable program code is carried. The propagated data signal may be in a plurality of forms, and includes, but is not limited to, an electromagnetic signal, an optical signal, or any suitable combination thereof. The computer-readable signal medium may also be any other computer-readable medium except the computer-readable storage medium. The computer-readable medium is capable of sending, propagating, or transmitting a program used by an instruction execution system, apparatus, or device, or a combination thereof.

The program code included in the computer-readable medium may be transmitted by any appropriate medium, including but not limited to wireless, wired, an optical cable, radio frequency (RF), etc., or any appropriate combination thereof.

The computer program code for executing operations in the present disclosure may be compiled in one or more programming languages or a combination thereof. The programming languages include object-oriented programming languages, such as Java, Smalltalk, and C++, and further include conventional procedural programming languages, such as “C” language or similar programming languages. The program code may be completely or partially executed on a user computer, executed as a separate software package, partially executed on a user computer and partially executed on a remote computer, or completely executed on a remote computer or server. In a case involving a remote computer, the remote computer may be connected to a user computer through any network including a local area network (LAN) or a wide area network (WAN), or may be connected to an external computer (for example, connected through the Internet by using an Internet service provider).

Finally, it should be noted that the foregoing embodiments are merely used for illustrating rather than limiting the technical solutions of the present disclosure; although the present disclosure is described in detail with reference to the foregoing embodiments, those of ordinary skill in the art should understood that the technical solutions described in the foregoing embodiments can be modified, or some or all technical features can be equivalently substituted; and such modifications or substitutions do not make the essence of the corresponding technical solutions depart from the technical solutions of the present disclosure.

1: A method for scaling a vehicle crash dummy model, comprising:
obtaining a height ratio, a girth ratio, and a mass ratio of each part of a body shape of a target population to a reference population, wherein the target population is formed by selecting a first group of individuals, and measurement is conducted on the individuals of the first group to form physical signs; and the reference population is formed by selecting a second group of individuals different from the first group, and measurement is conducted on the individuals of the second group to form physical signs;
calculating part scaling ratios of the target population to the reference population in a height direction and each direction in a girth plane according to the height ratio, the girth ratio, and the mass ratio; specifically, determining, according to the girth ratio S, size ratios λₓ and λ_{y} of the target population to the reference population in two directions perpendicular to each other in the girth plane: λₓ=λ_{y}=S; solving correction coefficients δₓ, δ_{y}, and δ_{z} of the height ratio λ_{z} and the size ratios λₓ and λ_{y} according to the mass ratio Rₘ and the following formulas: Rₘ=λₓ×λ_{y}×λ_{z}×δₜₒₜₐₗ, δₜₒₜₐₗ=δₓ×δ_{y}×δ_{z}, δₓ=δ_{y}, and (λₓ×λ_{y})/λ_{z}=(δₓ×δ_{y})/δ_{z}, wherein δₜₒₜₐₗ represents a correction coefficient for correcting a relationship between λₓ×λ_{y}×λ_{z} and the mass ratio; and calculating a part scaling ratio λ_{zcorrection} in the height direction, a part scaling ratio λ_{xcorrection} in one of the two directions, and a part scaling ratio λ_{ycorrection} in the other of the two directions of the target population to the reference population according to the following formulas: λ_{zcorrection}=λ_{z}×δ_{z}, λ_{xcorrection}=λₓ×δₓ, and λ_{ycorrection}=λₓ×δ_{y};
scaling simulation models of each part of a dummy simulation model of the reference population conforming to the physical signs of the reference population according to each scaling ratio; and
assembling scaled models of each part, to obtain a dummy simulation model of the target population conforming to the physical signs of the target population.

2: The method according to claim 1, wherein the obtaining a height ratio, a girth ratio, and a mass ratio of each part of a body shape of a target population to a reference population comprises:
dividing a calf height of the target population and a calf height of the reference population into N equal parts respectively, wherein N is a natural number greater than 2 and N is equal to 4;
determining girth ratios of the target population to the reference population at N−1 division lines respectively; and
determining the girth ratio of the part of the target population to the reference population according to N−1 girth ratios.

3: The method according to claim 1, wherein the scaling simulation models of each part of a dummy simulation model of the reference population according to each scaling ratio comprises:
obtaining a center of mass of any part of a physical dummy of the reference population under a specific posture;
adjusting the simulation model of the part of the dummy simulation model of the reference population to the specific posture; and
scaling the simulation model of the part according to each scaling coefficient with the center of mass as a center.

4: The method according to claim 1, wherein the dummy simulation model of the target population is used for manufacturing a physical dummy of the target population.

5: The method according to claim 1, wherein each part comprise at least one of the following parts: a head, a neck, a chest, buttocks, an upper left arm, a lower left arm, a left hand, an upper right arm, a lower right arm, a right hand, a left thigh, a left calf, a left foot, a right thigh, a right calf, and a right foot.

6: The method according to claim 1, wherein the target population is a Chinese population with 10 percentiles of adult male figures, and the reference population is a Chinese population with 50 percentiles of adult male figures.

7: An electronic device, comprising:
one or more processors; and
a memory, used for storing one or more program, wherein
when the one or more programs are executed by the one or more processors, the one or more processors are enabled to implement the method for scaling a vehicle crash dummy model according to claim 1.

8: A non-transitory computer-readable storage medium, storing a computer program, wherein the program, when executed by a processor, implements the method for scaling a vehicle crash dummy model according to claim 1.
